(19) United States
(12) Patent Application Publication
(10) Pub. No.: US 2025/0113495 A1
(43) Pub. Date: Apr. 3, 2025

(54) SEMICONDUCTOR DEVICE AND MANUFACTURING METHOD THEREOF

(71) Applicant: United Microelectronics Corp., Hsinchu (TW)

(72) Inventors: Wen-Jen Wang, Tainan City (TW); Yu-Huan Yeh, Taichung City (TW); Chuan-Fu Wang, Miaoli County (TW)

(73) Assignee: United Microelectronics Corp., Hsinchu (TW)

(21) Appl. No.: 18/494,786

(22) Filed: Oct. 26, 2023

(30) Foreign Application Priority Data
Oct. 3, 2023 (TW) 112137832

(51) Int. Cl. H10B 63/00; H01L 21/768; H01L 23/522; H01L 23/528

(52) U.S. Cl. CPC H10B 63/00; H01L 21/76807; H01L 21/7684; H01L 21/76877; H01L 23/5226; H01L 23/5283

(57) ABSTRACT

A semiconductor device includes a resistive random access memory (RRAM) device, a dual damascene structure, and a spacer. The dual damascene structure is disposed near the RRAM device, and the spacer is disposed in a sidewall of the RRAM device. The RRAM device includes a lower electrode, a metal oxide layer, and an upper electrode. The metal oxide layer is disposed on the lower electrode, and the upper electrode is disposed on the metal oxide layer. The dual damascene structure includes a via and a wire disposed on the via, in which a top part of the wire is coplanar with a top part of the upper electrode in the RRAM device.

### CROSS-REFERENCE TO RELATED APPLICATION

This application claims the priority benefit of Taiwan application serial no. 112137832, filed on Oct. 3, 2023. The entirety of the above-mentioned patent application is hereby incorporated by reference herein and made a part of this specification.

### BACKGROUND

### Technical Field

The disclosure relates to a semiconductor device and a manufacturing method thereof, and in particular to a semiconductor device and a manufacturing method thereof that simultaneously form a resistive random access memory (RRAM) device and internal connections.

### Description of Related Art

A RRAM device is a type of non-volatile memory which has characteristics of small memory cell size, ultra-high-speed operation, low-power operation, and high durability. Therefore, the device has become a type of non-volatile memory that has been widely studied in recent years. However, the manufacturing process of the RRAM device requires at least three mask processes. Moreover, there is currently no research on integrating the manufacturing process of the RRAM device and the manufacturing process of a dual damascene structure.

### SUMMARY

The disclosure provides a semiconductor device which can manufacture a resistive random access memory (RRAM) device and a dual damascene structure with few mask processes.

The disclosure also provides a manufacturing method of a semiconductor device, which can integrate the manufacturing process of the RRAM device and the manufacturing process of the dual damascene structure.

The semiconductor device according to the disclosure includes a resistive random access memory (RRAM) device, a dual damascene structure, and a spacer. The dual damascene structure is disposed near the RRAM device, and the spacer is disposed in the sidewall of the RRAM device. The RRAM device includes a lower electrode, a metal oxide layer, and an upper electrode. The metal oxide layer is disposed on the lower electrode, and the upper electrode is disposed on the metal oxide layer. The dual damascene structure includes a via and a wire disposed on the via, in which a top part of the wire is coplanar with a top part of the upper electrode in the RRAM device.

In an embodiment of the disclosure, the top part of the spacer may also be coplanar with the top part of the upper electrode of the RRAM device.

In an embodiment of the disclosure, the top part of the spacer may be coplanar with the top part of the wire.

In an embodiment of the disclosure, in a cross-sectional view, the shape of the spacer is formed in a rectangle.

In an embodiment of the disclosure, in the cross-sectional view, the thickness of the spacer positioned on the right side of the RRAM device is different from the thickness of the spacer positioned on the left side of the RRAM device.

In an embodiment of the disclosure, the metal oxide layer is formed in a U-shape.

In an embodiment of the disclosure, the bottom surface of the lower electrode is coplanar with the bottom part of the dual damascene structure.

In an embodiment of the disclosure, the material of the lower electrode may be titanium, the material of the metal oxide layer may be hafnium oxide, and the material of the upper electrode may be titanium nitride.

The manufacturing method of the semiconductor device according to the disclosure includes forming a dielectric layer on a base having a metal layer, forming an opening in the dielectric layer to expose the metal layer, forming a spacer in the sidewall of the opening, forming a lower electrode on the bottom part of the opening, conformally forming a metal oxide layer on the lower electrode, forming an upper electrode on the metal oxide layer and filling the opening, forming a dual damascene hole having a void and a trench in the dielectric layer near the opening, filling the dual damascene hole with a conducting material, and then performing a planarization process to simultaneously remove part of the conducting material and part of the upper electrode.

In another embodiment of the disclosure, the method of forming the spacer includes first filling the opening with a nitride layer, forming a patterned mask on the dielectric layer and exposing part of the nitride layer, and then by using the patterned mask as an etching mask, etching the exposed part of the nitride layer until the metal layer is exposed.

In another embodiment of the disclosure, the method of forming the spacer includes conformally depositing a nitride layer on the inner surface of the opening and then back etching the nitride layer until the metal layer is exposed.

In another embodiment of the disclosure, the step of forming the upper electrode includes forming a redundant portion on the dielectric layer other than the opening. The method of forming the dual damascene hole includes patterning the redundant portion on the dielectric layer to form a first patterned mask, etching the dielectric layer to form the trench in the dielectric layer by using the first patterned mask as an etching mask, forming a second patterned mask in the trench to expose part of the dielectric layer, and then etching the dielectric layer to form the void in the dielectric layer below the trench by using the second patterned mask as an etching mask.

In another embodiment of the disclosure, the method of forming the lower electrode includes filling the opening with a conducting layer, planarizing the conducting layer, and then back etching the conducting layer.

In order to make the above-mentioned features of the disclosure more comprehensible, the embodiments are described in detail below with the accompanying drawings.

### BRIEF DESCRIPTION OF THE DRAWINGS

FIG. 1 is a schematic cross-sectional view of a semiconductor device according to the first embodiment of the disclosure.

FIG. 2A to FIG. 2N are schematic cross-sectional views of a manufacturing process of a semiconductor device according to the second embodiment of the disclosure.

### DESCRIPTION OF THE EMBODIMENTS

The disclosure is applied to a semiconductor device including a resistive random access memory (RRAM) device and internal connections, and through device and process design, the position and height of the RRAM device may be the same or similar to the dual damascene structure in the internal connections, in particular, in terms of manufacturing process, at least one mask process can be reduced, thereby reducing manufacturing costs, and the process can be integrated with the manufacturing process of internal connections.

Some embodiments are listed below to illustrate the disclosure, but the disclosure is not limited to the multiple embodiments listed. The possibility of combining the multiple embodiments is also allowed.

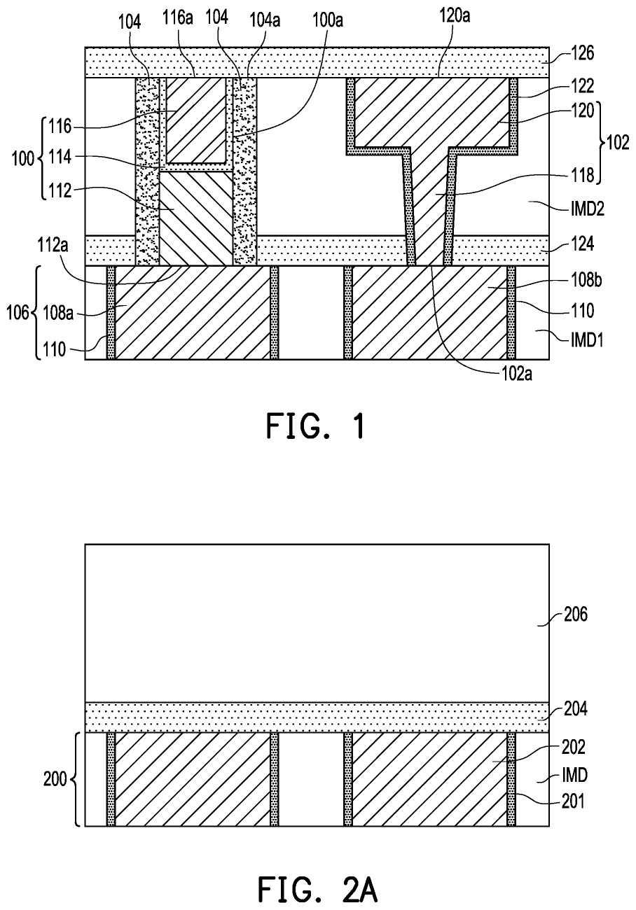

FIG. 1 is a schematic cross-sectional view of a semiconductor device according to the first embodiment of the disclosure.

Please refer to FIG. 1. The semiconductor device according to the first embodiment basically includes a RRAM device 100, a dual damascene structure 102, and a spacer 104. The dual damascene structure 102 is disposed near the RRAM device 100, and the spacer 104 is disposed in a sidewall 100a of the RRAM device 100. In an embodiment, the RRAM device 100 and the dual damascene structure 102 may be disposed on a base 106. Generally, the base 106 includes a semiconductor base (not shown), a dielectric layer IMD1 thereon, and a metal layer 108a and a metal layer 108b formed in the dielectric layer IMD1. The material of the dielectric layer IMD1 is, for example, but not limited to, undoped silicate glass (USG), phosphosilicate glass (PSG), borosilicate glass (BSG), boron-doped phosphosilicate glass (BPSG), fluorine-doped silicate glass (FSG), silicon oxide (SiO₂), SiOC-based material, or other suitable extremely low dielectric constant (ELK) or ultra low dielectric constant (ULK) materials. The material of the metal layer 108a and the metal layer 108b is, for example, copper (Cu) or other suitable metal materials, such as cobalt (Co), aluminum (Al), tungsten (W), nickel (Ni), platinum (Pt), tantalum (Ta), or titanium (Ti). A barrier layer 110 may be disposed between the metal layer 108a and the dielectric layer IMD1, and similarly, another barrier layer 110 may be disposed between the metal layer 108b and the dielectric layer IMD1. The material of the barrier layer 110 is, for example, but not limited to, titanium (Ti), titanium nitride (TiN), tantalum (Ta), tantalum nitride (TaN), or a stack layer comprising the above materials. Although there is no special indication in FIG. 1, it should be noted that there may be other internal connections, such as metal layers or contacts formed under the dielectric layer IMD1, and so on. The material of the dual damascene structure 102 is, for example, but not limited to, a group comprising Cu, Co, Al, W, Ni, Pt, Ta, Ti, titanium aluminum alloy (TiAl), cobalt tungsten phosphide (CoWP), etc., but not limited thereto.

In FIG. 1, the RRAM device 100 includes a lower electrode 112, a metal oxide layer 114, and an upper electrode 116. The metal oxide layer 114 is disposed on the lower electrode 112, and the upper electrode 116 is disposed on the metal oxide layer 114. The lower electrode 112 is connected to the metal layer 108a to achieve the electrical connection. The material of the lower electrode 112 is, for example, titanium (Ti) or other suitable conducting materials, such as tantalum (Ta), titanium nitride (TiN), tantalum nitride (TaN), platinum (Pt), iridium (Ir), ruthenium (Ru), aluminum (Al), copper (Cu), gold (Au), tungsten (W). The material of the upper electrode 116 is, for example, titanium nitride or other suitable conducting materials, such as titanium, tantalum, tantalum nitride, platinum, iridium, ruthenium, aluminum, copper, gold, tungsten. The material of the metal oxide layer 114 is, for example, hafnium oxide (HfO₂) or other suitable metal oxides, such as nickel oxide (NiO), titanium oxide (TiO), zinc oxide (ZnO), zirconium oxide (ZrO), tantalum oxide (TaO), or other transition metal oxides (TMO), but not limited thereto. In addition, due to the manufacturing process, the metal oxide layer 114 may extend to two sides of the upper electrode 116 and directly contact the spacer 104, so the metal oxide layer 114 is formed in a U-shape. The dual damascene structure 102 generally includes a via 118 and a wire 120 disposed on the via 118, in which the via 118 is connected to the metal layer 108b to achieve the electrical connection. In the first embodiment, a top part 120a of the wire 120 is coplanar with a top part 116a of the upper electrode 116 in the RRAM device 100, so the wire 120 and the upper electrode 116 can be obtained through the same planarization process, which can integrate the manufacturing process of the RRAM device 100 and the dual damascene structure 102. In an embodiment, a bottom surface 112a of the lower electrode 112 is coplanar with a bottom part 102a of the dual damascene structure 102. The RRAM device 100 and the dual damascene structure 102 are generally formed in a dielectric layer IMD2. The material of the dielectric layer IMD2 is, for example, but not limited to, USG, PSG, BSG, BPSG, FSG, SiO₂, SiOC-based materials, or other suitable ELK or ULK materials. In addition, a barrier layer 122 may be disposed between the dual damascene structure 102 and the dielectric layer IMD2, a cover layer 124 may be formed on the dielectric layer IMD1, and a cover layer 126 may also be formed on the dielectric layer IMD2. The material of the barrier layer 122 is, for example, but not limited to, titanium (Ti), titanium nitride (TiN), tantalum (Ta), tantalum nitride (TaN), or a stack layer comprising the above materials. The materials of the cover layer 124 and the cover layer 126 may independently include silicon nitride (SiN), silicon oxynitride (SiON), silicon nitride carbide (SiCN), or nitrogen doped carbon (NDC), but not limited thereto.

Since the key to the operation of the RRAM device 100 lies in the thickness of the metal oxide layer 114, as long as the thickness of the metal oxide layer 114 is controlled within a required range, the sizes (such as the thicknesses) of the upper electrode 116 and the lower electrode 112 may be adjusted. Therefore, in addition to the upper electrode 116 and the lower electrode 112 having almost the same thickness in FIG. 1, a thick lower electrode 112 may also be used with a thin upper electrode 116. Alternatively, a thin lower electrode 112 may be used with a thick upper electrode 116. In an embodiment, a top part 104a of the spacer 104 may also be coplanar with the top part 116a of the upper electrode 116 of the RRAM device 100. In an embodiment, the top part 104a of the spacer 104 may be coplanar with the top part 120a of the wire 120.

Please continue to refer to FIG. 1. In the cross-sectional view, the shape of the spacer 104 may be formed in a rectangle. That is to say, the thickness difference between the upper end and the lower end of the spacer 104 is small, so the upper half of the spacer 104 can have a sufficient thickness, so as to make a significant effect in preventing the diffusion of oxygen atoms. In an embodiment, the material of the spacer 104 is, for example, silicon nitride or other suitable dielectric materials, such as silicon oxynitride or silicon nitride carbide.

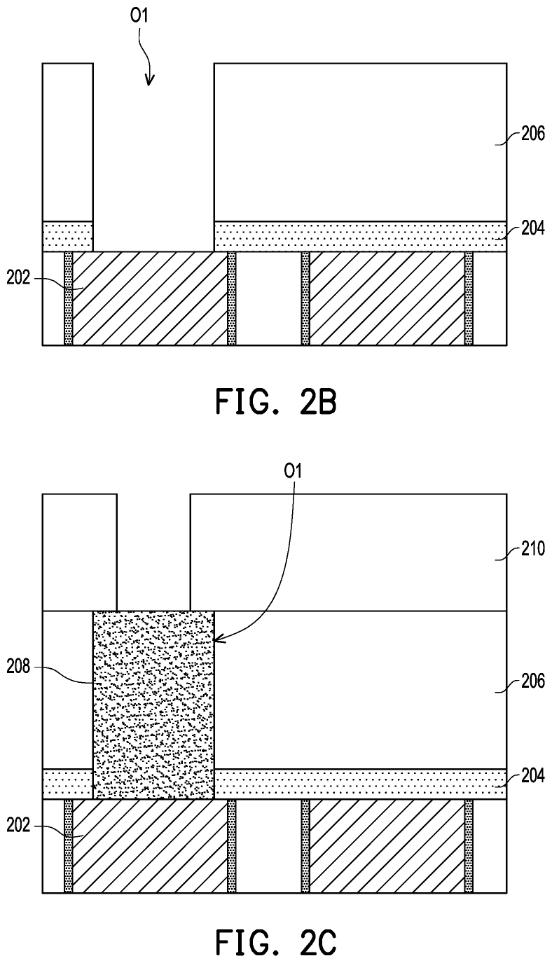

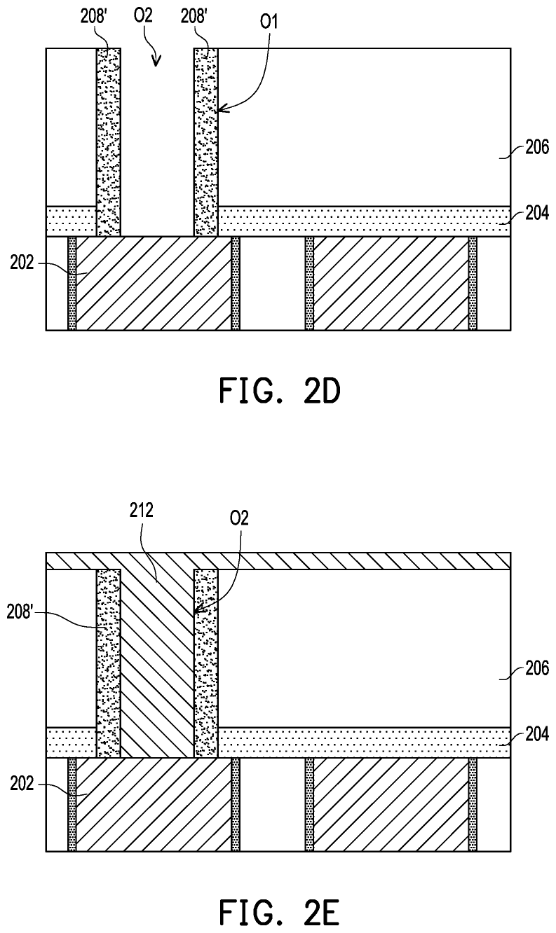

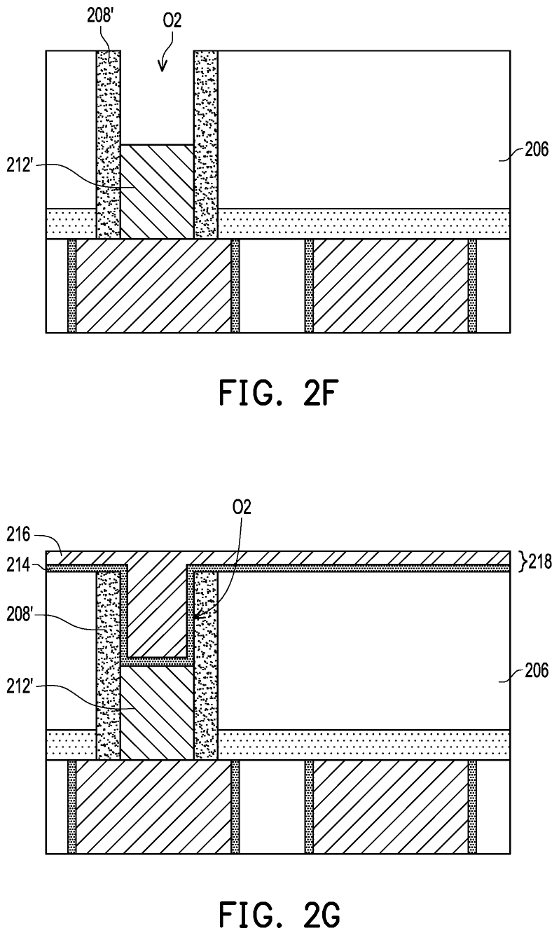

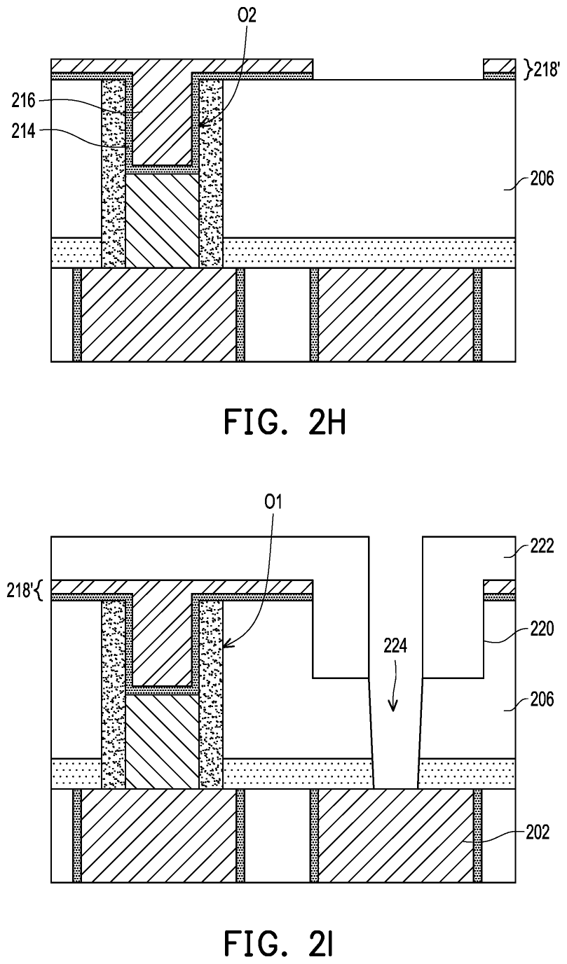

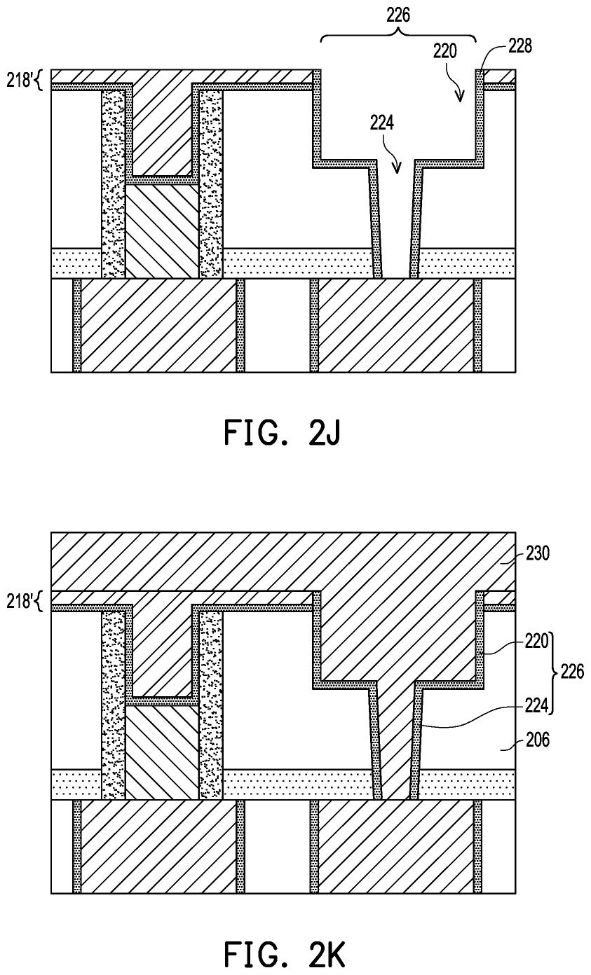

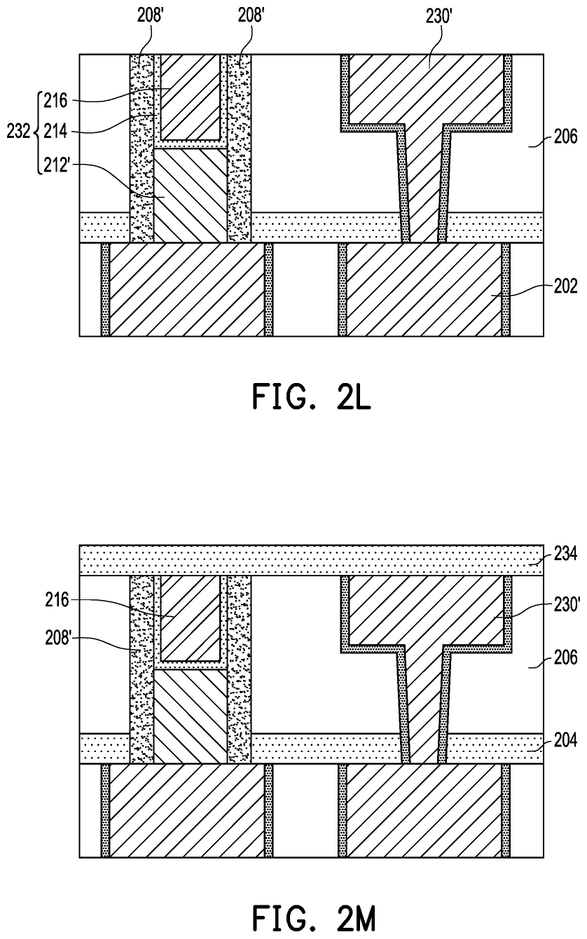

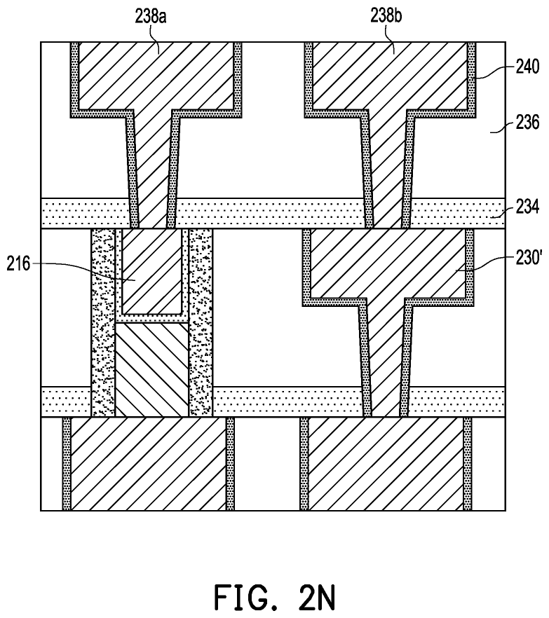

FIG. 2A to FIG. 2N are schematic cross-sectional views of a manufacturing process of a semiconductor device according to the second embodiment of the disclosure.

Please refer to FIG. 2A first. A dielectric layer 206 is formed on a base 200 having a metal layer 202. The base 200 may include a semiconductor base (not shown), a dielectric layer IMD thereon, and the metal layer 202, etc. The materials of the dielectric layer 206 and the dielectric layer IMD each independently include, but not limited to, USG, PSG, BSG, BPSG, FSG, SiO₂, SiOC-based materials, or other suitable ELK or ULK materials. The material of the metal layer 202 is, for example, copper or other suitable metal materials, such as Co, Al, W, Ni, Pt, Ta, or Ti. A barrier layer 201 may be formed between the metal layer 202 and the dielectric layer IMD. The material of the barrier layer 201 is, for example, but not limited to, Ti, TiN, Ta, TaN, or a stack layer comprising the above materials. Although there is no special indication in FIG. 2A, it should be noted that there may be other internal connections, such as metal layers or contacts formed under the dielectric layer IMD1, and so on. In an embodiment, a cover layer 204 may be formed on the base 200 before forming the dielectric layer IMD, in which the material of the cover layer 204 may include SiN, SiON, SiCN, or NDC, but not limited thereto.

Next, please refer to FIG. 2B. By using a photolithography process, an opening O1 is formed in the dielectric layer 206 to expose the metal layer 202. The method of forming the opening O1 is, for example, a photolithography etching process. During the etching process, part of the dielectric layer 206 is removed, and then the cover layer 204 is continued to be etched, until part of the metal layer 202 is exposed.

Afterward, please refer to FIG. 2C. In order to form a spacer in the sidewall of the opening O1, a nitride layer 208 may first be used to fill the opening O1, in which the material of the nitride layer 208 is, for example, silicon nitride or other suitable dielectric materials, such as silicon oxynitride or silicon nitride carbide. Moreover, after the opening O1 is filled with the nitride layer 208, a planarization process may be required to remove nitrides other than the opening O1. Next, by using another photolithography process, a patterned mask 210 is formed on the dielectric layer 206, and part of the nitride layer 208 is exposed. The patterned mask 210 may be a photoresist layer or other material layers that have an etching selectivity ratio with the nitride layer 208.

Then, please refer to FIG. 2D. By using the patterned mask 210 in FIG. 2C as an etching mask, the exposed part of the nitride layer 208 in FIG. 2C is etched until the metal layer 202 is exposed, and a narrow opening O2 is formed in the original opening O1. Then, the patterned mask 210 is removed. In the cross-sectional view, the shape of a spacer 208′ formed according to the above step is approximately formed in a rectangle. That is to say, the thickness difference between the upper end and the lower end of the spacer 208′ is small. Also, in the cross-sectional view, after the above two photolithography processes, the thickness of the obtained spacer 208′ on the left side may be different from the thickness of the obtained spacer 208′ on the right side, but the spacer 208′ serving as a protective layer is not affected. In another embodiment, the spacer 208′ may also be manufactured by using a general spacer process. For example, a nitride layer is conformally deposited on the inner surface of the opening O1, and then back etching is performed until the metal layer 202 is exposed.

Next, please refer to FIG. 2E. In order to form a lower electrode on the bottom part of the opening O2, the opening may be filled with a conducting layer 212. The formation method of the conducting layer 212 is, for example, evaporation or other suitable deposition methods, and the material of the conducting layer 212 is, for example, Ti or other suitable conducting materials, such as Ta, TiN, TaN, Pt, Ir, Ru, Al, Cu, Au, or W.

Subsequently, please refer to FIG. 2F. After the conducting layer 212 in FIG. 2E is planarized and back etched, a lower electrode 212′ may be obtained, in which the etchant used for the above back etching is, for example, sulfuric acid. Since the key to the operation of the RRAM device lies in the thickness of the metal oxide layer, the thickness of the lower electrode 212′ may be adjusted, for example, to be thicker or thinner than in FIG. 2F.

Then, referring to FIG. 2G, a metal oxide layer 214 is conformally formed on the lower electrode 212′, in which the material of the metal oxide layer 214 is, for example, HfO₂ or other suitable metal oxides, such as nickel oxide, titanium oxide, zinc oxide, zirconium oxide, tantalum oxide, or other transition metal oxides (TMO), but not limited thereto. Afterward, an upper electrode 216 is formed on the metal oxide layer 214 and the opening O2 is filled, in which the material of the upper electrode 216 is, for example, titanium nitride or other suitable conducting materials, such as titanium, tantalum, tantalum nitride, platinum, iridium, ruthenium, aluminum, copper, gold, tungsten. When the upper electrode 216 is formed, a redundant portion 218 is formed on the dielectric layer 206 other than the opening O2. The redundant portion 218 may also include the metal oxide layer 214, in which the thickness of the redundant portion 218 may be 100 Å to 200 Å.

Next, referring to FIG. 2H, in order to form a dual damascene hole in the dielectric layer 206 near the opening O2, the redundant portion 218 in FIG. 2G may be patterned first to form a first patterned mask 218′ on the dielectric layer 206, and a predetermined portion to form the dual damascene hole is exposed.

Then, referring to FIG. 2I, by using the first patterned mask 218′ as an etching mask, the dielectric layer 206 is etched to form a trench 220 in the dielectric layer 206, and the trench 220 may extend into the page. Then, a second patterned mask 222 is formed in the trench 220 to expose part of the dielectric layer 206, and by using the second patterned mask 222 as an etching mask, the dielectric layer 206 is etched to form a void 224 in the dielectric layer 206 below the trench 220. The second patterned mask 222 also covers the remaining parts, so the surrounding structures are not affected during the etching of the void 224.

Next, referring to FIG. 2J, after removing the second patterned mask 222 in FIG. 2I, a barrier layer 228 may be formed on the inner surface of a dual damascene hole 226 formed by the trench 220 and the void 224, in which the material of the barrier layer 228 is, for example, but not limited to, Ti, TiN, Ta, TaN, or a stack layer comprising of the above materials.

Then, referring to FIG. 2K, the dual damascene hole 226 is filled with a conducting material 230, in which the conducting material 230 is, for example, but not limited to, a group comprising Cu, Co, Al, W, Ni, Pt, Ta, Ti, TiAl, CoWP, etc., but not limited thereto.

Next, referring to FIG. 2L, a planarization process (such as a CMP process) is performed to simultaneously remove part of the conducting material and part of the upper electrode 216, so as to obtain a dual damascene structure 230′ and a RRAM device 232 positioned near the dual damascene structure 230′, in which the RRAM device 232 includes the lower electrode 212′, the metal oxide layer 214, and the upper electrode 216. Since the removed parts contain different materials, the planarization process may require segmented grinding by using different grinding materials.

Next, referring to FIG. 2M, the connection structure may be continued to be formed on the completed semiconductor device, for example, a cover layer 234 is formed first to cover the dielectric layer 206, the dual damascene structure 230′, the upper electrode 216, and the spacer 208′, etc. Regarding the material of the cover layer 234, reference may be made to the cover layer 204, so details will not be repeated here.

Subsequently, please refer to FIG. 2N. After a dielectric layer 236 is formed, a dual damascene structure 238a and a dual damascene structure 238b may be formed therein, a barrier layer 240 may be formed between the dual damascene structure 238a and the dielectric layer 236, and similarly, the barrier layer 240 may be formed between the dual damascene structure 238b and the dielectric layer 236. Regarding the formation method of the dielectric layer 236, the dual damascene structure 238a, and the dual damascene structure 238b, reference may be made to the manufacturing process of the dual damascene structure 230′ in FIG. 2H to FIG. 2L, so details will not be repeated here. The dual damascene structure 238a is connected to the upper electrode 216, and the dual damascene structure 238b is connected to the dual damascene structure 230′.

In this embodiment, the opening O1 is formed first, then the spacer 208′ is formed in the sidewall of the opening O1, and the RRAM device 232 is deposited and formed in the opening O2, and further a series of planarization processes are performed. Therefore, at least one photomask process can be omitted. In addition, before the planarization process of the RRAM device 232, the dual damascene structure 230′ is formed, then, the top part of the dual damascene structure 230′ can be planarized while the RRAM device 232 is being planarized, and thereby the integration of the manufacturing process of the RRAM device 232 and the dual damascene structure 230′ is achieved.

Although the disclosure has been disclosed above in the embodiments, the embodiments are not intended to limit the disclosure. Persons with ordinary knowledge in the technical field can make some changes and modifications without departing from the spirit and scope of the disclosure. Therefore, the protection scope of the disclosure shall be determined by the appended claims.

What is claimed is:

1. A semiconductor device, comprising:
a resistive random access memory (RRAM) device;
a dual damascene structure disposed near the RRAM device; and
a spacer disposed in a sidewall of the RRAM device, wherein
the RRAM device comprises:
a lower electrode;
a metal oxide layer disposed on the lower electrode; and
an upper electrode disposed on the metal oxide layer;
the dual damascene structure comprises:
a via; and
a wire disposed on the via, wherein a top part of the wire is coplanar with a top part of the upper electrode of the RRAM device.

2. The semiconductor device as claimed in claim 1, wherein a top part of the spacer is coplanar with the top part of the upper electrode of the RRAM device.

3. The semiconductor device as claimed in claim 1, wherein a top part of the spacer is coplanar with the top part of the wire.

4. The semiconductor device as claimed in claim 1, wherein in a cross-sectional view, a shape of the spacer is formed in a rectangle.

5. The semiconductor device as claimed in claim 1, wherein in a cross-sectional view, a thickness of the spacer positioned on a right side of the RRAM device is different from a thickness of the spacer positioned on a left side of the RRAM device.

6. The semiconductor device as claimed in claim 1, wherein the metal oxide layer is formed in a U-shape.

7. The semiconductor device as claimed in claim 1, wherein a bottom surface of the lower electrode is coplanar with a bottom part of the dual damascene structure.

8. The semiconductor device as claimed in claim 1, wherein a material of the lower electrode comprises titanium, a material of the metal oxide layer comprises hafnium oxide, and a material of the upper electrode comprises titanium nitride.

9. A manufacturing method of a semiconductor device, comprising:
forming a dielectric layer on a base having a metal layer;
forming an opening in the dielectric layer to expose the metal layer;
forming a spacer in a sidewall of the opening;
forming a lower electrode on a bottom part of the opening;
conformally forming a metal oxide layer on the lower electrode;
forming an upper electrode on the metal oxide layer and filling the opening;
forming a dual damascene hole having a void and a trench in the dielectric layer near the opening;
filling the dual damascene hole with a conducting material; and
performing a planarization process to simultaneously remove a part of the conducting material and a part of the upper electrode.

10. The manufacturing method of the semiconductor device as claimed in claim 9, wherein a method of forming the spacer comprises:
filling the opening with a nitride layer;
forming a patterned mask on the dielectric layer and exposing a part of the nitride layer; and
by using the patterned mask as an etching mask, etching the exposed part of the nitride layer until the metal layer is exposed.

11. The manufacturing method of the semiconductor device as claimed in claim 9, wherein a method of forming the spacer comprises:
conformally depositing a nitride layer on an inner surface of the opening; and
back etching the nitride layer until the metal layer is exposed.

12. The manufacturing method of the semiconductor device as claimed in claim 9, wherein a step of forming the upper electrode comprises forming a redundant portion on the dielectric layer other than the opening, and a method of forming the dual damascene hole comprises:
patterning the redundant portion on the dielectric layer to form a first patterned mask;
by using the first patterned mask as an etching mask, etching the dielectric layer to form the trench in the dielectric layer;
forming a second patterned mask in the trench to expose a part of the dielectric layer; and
by using the second patterned mask as an etching mask, etching the dielectric layer to form the void in the dielectric layer below the trench.

13. The manufacturing method of the semiconductor device as claimed in claim 9, wherein a method of forming the lower electrode comprises:
filling the opening with a conducting layer;
planarizing the conducting layer; and
back etching the conducting layer.
